(19) United States
(12) Patent Application Publication
(10) Pub. No.: US 2019/0058147 A1
(43) Pub. Date: Feb. 21, 2019

(54) LIGHT EMITTING DIODE DEVICE, LIGHT SOURCE STRUCTURE AND ELECTRONIC APPARATUS

(71) Applicants: BOE TECHNOLOGY GROUP CO., LTD., Beijing (CN); FUZHOU BOE OPTOELECTRONICS TECHNOLOGY CO., LTD., Fuzhou (CN)

(72) Inventors: Jie LIU, Beijing (CN); Kai DIAO, Beijing (CN); Hongyu ZHAO, Beijing (CN); Han ZHANG, Beijing (CN); Zongjie BAO, Beijing (CN)

(21) Appl. No.: 15/977,574

(22) Filed: May 11, 2018

(30) Foreign Application Priority Data
Aug. 21, 2017 (CN) 201721049430.8

(51) Int. Cl. H01L 51/52; H01L 51/50; H01L 33/48; H01L 33/36

(52) U.S. Cl. CPC H01L 51/5203; H01L 33/36; H01L 33/486; H01L 51/5036

(57) ABSTRACT

A light emitting diode device, a light source structure and an electronic apparatus are provided. The light emitting diode device includes: a support structure; at least one light emitting diode, provided on the support structure; and a first electrode and a second electrode, provided at a bottom of the support structure and respectively electrically connected with the light emitting diode. The first electrode and the second electrode respectively include a first end, and the first end of the first electrode and the first end of the second electrode extend beyond an outer contour of the bottom of the support structure in a direction parallel to the bottom of the support structure.

### TECHNICAL FIELD

Embodiments of the present disclosure relate to a light emitting diode device, a light source structure and an electronic apparatus.

### BACKGROUND

An organic light emitting diode (LED) is applied very widely; it can be made into various forms such as dot, line, plane, and thus can be used for implementing a light and thin product. An internal working temperature of the LED is relatively high, the high temperature has a great impact on luminous efficiency and service life of the LED. Furthermore, poor heat dissipation of the LED shortens the life of the LED, so it is necessary to take measures for implementing heat dissipation.

### SUMMARY

According to embodiments of the disclosure, a light emitting diode device is provided. The light emitting diode device comprises: a support structure; at least one light emitting diode, provided on the support structure; and a first electrode and a second electrode, provided at a bottom of the support structure and respectively electrically connected with the light emitting diode. The first electrode and the second electrode respectively include a first end, and the first end of the first electrode and the first end of the second electrode extend beyond an outer contour of the bottom of the support structure in a direction parallel to the bottom of the support structure.

For example, the first electrode and the second electrode are of a straight strip shape and extend in the direction parallel to the bottom of the support structure.

For example, the first electrode and the second electrode respectively include a first portion and a bent portion connected with each other, the first portion of the first electrode and the first portion of the second electrode are parallel to the bottom of the support structure, and extend beyond the outer contour of the bottom of the support structure in the direction parallel to the bottom of the support structure, and the bent portion of the first electrode and the bent portion of the second electrode extend from an inner portion of the support structure beyond the bottom of the support structure in a direction perpendicular to the bottom of the support structure.

For example, the first electrode and the second electrode respectively include a first portion and a bent portion connected with each other, the first portion of the first electrode and the first portion of the second electrode are parallel to the bottom of the support structure, and extend beyond the outer contour of the bottom of the support structure in the direction parallel to the bottom of the support structure, and the bent portion of the first electrode and the bent portion of the second electrode extend from an inner portion of the support structure but not beyond the bottom of the support structure in a direction perpendicular to the bottom of the support structure.

For example, the light emitting diode device further comprises a fluorescent layer provided on the light emitting diode.

For example, the light emitting diode device further comprises a light emitting diode chip provided on the support structure, and the light emitting diode chip includes the light emitting diode.

For example, the light emitting diode device further comprises a reflection structure, and a reflective surface of the reflection structure and a light emission surface of the light emitting diode have an included angle.

For example, the support structure is a pillar or a bracket.

According to the embodiments of the disclosure, a light source structure is provided. The light source structure comprises: the light emitting diode device as described above and a circuit board. The light emitting diode device is provided in the circuit board, so that the light emitting diode device is embedded in the circuit board.

For example, the circuit board comprises a groove or a via hole penetrating through the circuit board, at least a portion of the light emitting diode device is provided in the via hole or the groove, and a light emission surface of the light emitting diode has a same orientation as that of the first surface of the circuit board.

For example, the support structure and the light emitting diode are located in the via hole, the first end of the first electrode and the first end of the second electrode are located on a side of the circuit board opposite to the first surface of the circuit board.

For example, a plurality of contact pads are provided on a second surface of the circuit board opposite to the first surface of the circuit board, and the contact pads are respectively electrically connected with the first end of the first electrode and the first end of the second electrode; or, a plurality of contact pads are provided in the groove, and the contact pads are respectively electrically connected with the first end of the first electrode and the first end of the second electrode.

For example, an insulating member is provided on the second surface of the circuit board to cover an exposed portion of the first end of the first electrode and an exposed portion of the first end of the second electrode.

For example, the light source structure further comprises a heat conductive layer provided on a second surface of the circuit board opposite to the first surface of the circuit board.

For example, the light source structure further comprises a heat dissipation layer covering the heat conductive layer.

According to the embodiments of the disclosure, an electronic apparatus is provided. The electronic apparatus comprises the light source structure as described above.

For example, the electronic apparatus is a display device, and the light source structure is configured as a backlight of the display device.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a cross-sectional schematic view of a light emitting diode device according one technique;

FIG. 2 is a cross-sectional schematic view of a light source structure according one technique;

FIG. 3A is a cross-sectional schematic view of a light emitting diode device provided by embodiments of the present disclosure;

FIG. 3B is another cross-sectional schematic view of the light emitting diode device provided by the embodiments of the present disclosure;

FIG. 3C is still another cross-sectional schematic view of the light emitting diode device provided by the embodiments of the present disclosure;

FIG. 4A is a plane schematic view of a light source structure provided by the embodiments of the present disclosure;

FIG. 4B is another plane schematic view of the light source structure provided by the embodiments of the present disclosure;

FIG. 5 is a cross-sectional schematic view taken along a line I-I′ in FIG. 4A or H-H′ in FIG. 4B;

FIG. 6 is another plane schematic view of the light source structure provided by the embodiments of the present disclosure;

FIG. 7 is a cross-sectional schematic view taken along a line G-G′ of FIG. 6;

FIG. 8 is a schematic view of a display device provided by the embodiments of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise specified, the technical terms or scientific terms here should be of general meaning as understood by those ordinarily skilled in the art. In specification and the claims, words such as “first”, “second” and the like do not denote any order, quantity, or importance, but rather are used for distinguishing different components. Words such as “include” or “comprise” and the like denote that elements or objects appearing before the words of “include” or “comprise” cover the elements or the objects enumerated after the words of “include” or “comprise” or equivalents thereof, not exclusive of other elements or objects. Words such as “inside”, “outside” and the like are only used for expressing relative positional relationship, when the absolute position of the described object is changed, the relative positional relationship may also be correspondingly changed.

Dimensions of accompanying drawings used in the present disclosure are not strictly drawn to scale. The number of light emitting diode devices in the light source structure is not limited to the number shown in the diagrams, and specific sizes and numbers of respective structures may be determined according to actual needs. The accompanying drawings as described in the present disclosure are merely schematic views.

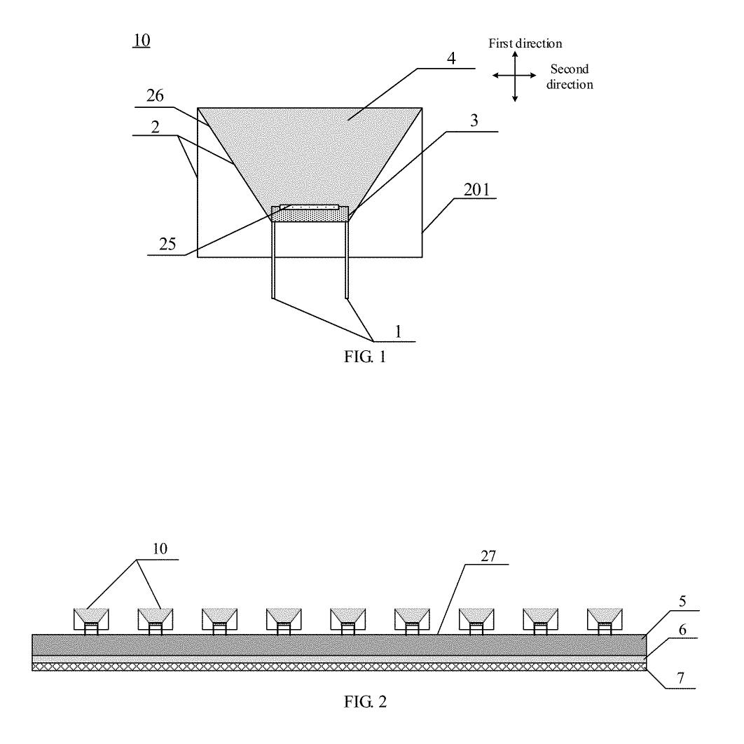

FIG. 1 is a cross-sectional schematic view of a light emitting diode device. As shown in FIG. 1, the light emitting diode device 10 comprises an electrode 1, a bracket 2, a chip 3 and a fluorescent layer 4. For example, the bracket 2 includes an accommodation portion 26 surrounded by a sidewall, a cross section of the accommodation portion 26 has a trapezoidal shape; the chip 3 is provided in the accommodation portion 26 of the bracket 2, for example, the chip 3 is provided at the bottom of the accommodation portion 26 and includes a light emitting diode 25; the fluorescent layer 4 is provided above the chip 3, for example, the fluorescent layer 4 is coated on the sidewall of the bracket 2 surrounding the accommodation portion 26 or covers the light emitting diode 25; a first end of the electrode I is electrically connected with the chip 3 so that the light emitting diode 25 in the chip 3 is electrically connected with a power source (not shown). For example, the electrode 1 extends beyond a bottom of the bracket 2 in a vertical direction (i.e. a first direction) but does not extend beyond an outer contour 201 of the bracket in a horizontal direction (i.e. a second direction) as shown in FIG. 1. For example, the light emitting diode device is an organic light emitting diode device.

FIG. 2 is a cross-sectional schematic view of a light source structure, the light source structure comprises a plurality of light emitting diode devices 10 shown in FIG. 1 and a circuit board 5. With reference to FIG. 1 and FIG. 2, each light emitting diode device 10 is provided on a first surface 27 of the circuit board 5, and a second end of the electrode 1 is electrically connected with a contact pad on the first surface 27 of the circuit board 5. The light source structure for example further comprises a heat conductive layer 6 covering a second surface of the circuit board 5 and a heat dissipation layer 7 covering the heat conductive layer 6, and the second surface of the circuit board 5 is a surface facing away from the first surface 27. In the light source structure comprising the light emitting diode device 10, the electrode 1 of the light emitting diode device 10 is so configured that the light emitting diode device 10 must be provided on the first surface of the circuit board 5, resulting in a relatively large thickness of the light source structure, which is not conducive to forming a light and thin product. In addition, in the light source structure, a heat dissipation path of the light emitting diode device 10 is that heat sequentially passes through the chip 3, the electrode 1, the circuit board 5, the heat conductive layer 6 and the heat dissipation layer 7 before being conducted to an external environment. The heat dissipation path is relatively long, which affects a heat dissipation speed, resulting in poor heat dissipation; the poor heat dissipation shortens the service life of the light emitting diode and also shortens the service life of the light source structure accordingly.

The embodiments of the present disclosure provide a light emitting diode device, the light emitting diode device comprises: a support structure, at least one light emitting diode, a first electrode and a second electrode. The at least one light emitting diode is provided on the support structure; the first electrode and the second electrode are provided at a bottom of the support structure and are respectively electrically connected with the light emitting diode; the first electrode and the second electrode respectively include a first end, and the first end of the first electrode and the first end of the second electrode respectively extend from the support structure and beyond an outer contour of the bottom of the support structure.

The embodiments of the present disclosure further provide a light source structure, the light source structure comprises at least one light emitting diode device as described above and a circuit board, the light emitting diode device is provided in the circuit board, so that the light emitting diode is embedded in the circuit board.

The embodiments of the present disclosure further provide an electronic apparatus, and the electronic apparatus comprises the above-described light source structure.

Hereinafter, the light emitting diode device, the light source structure and the electronic apparatus according to the embodiments of the present disclosure will be described in detail in conjunction with the accompanying drawings.

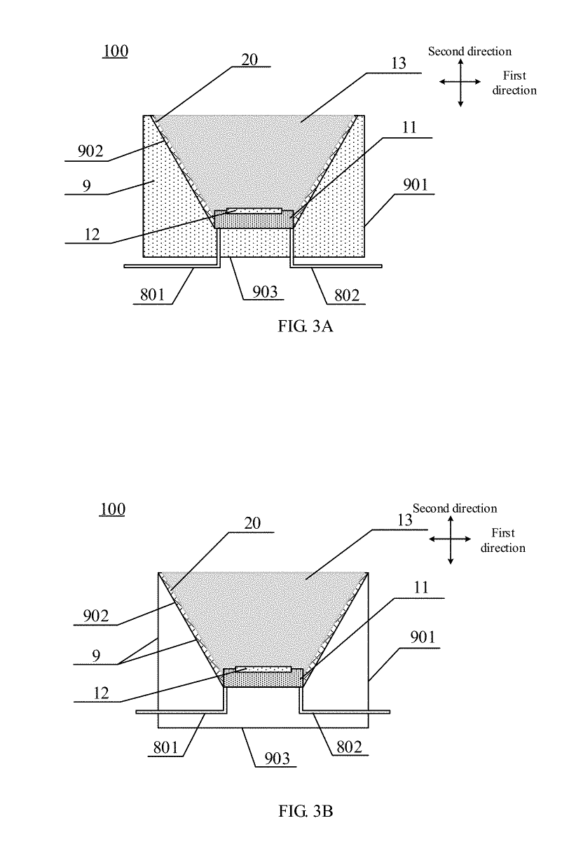

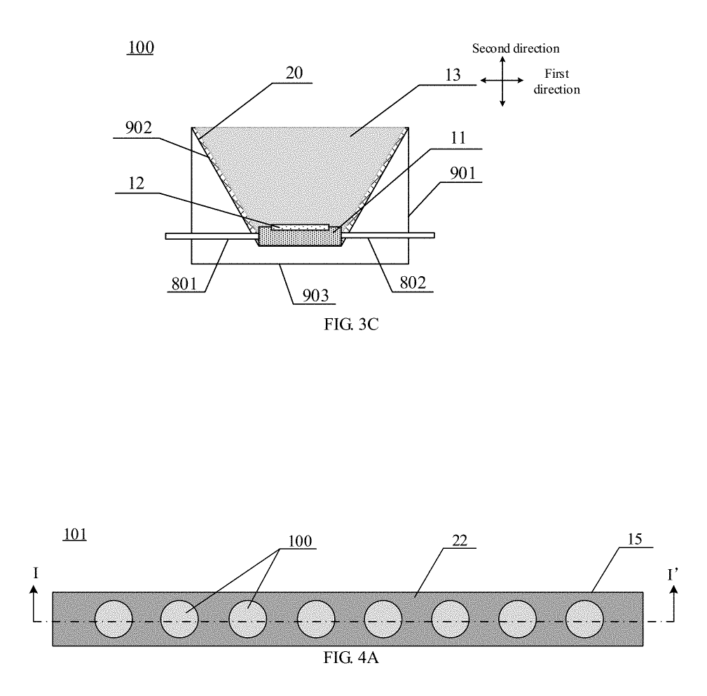

FIG. 3A is a cross-sectional schematic view of the light emitting diode device provided by the embodiments of the present disclosure, FIG. 3B is another cross-sectional schematic view of the light emitting diode device provided by the embodiments of the present disclosure, and FIG. 3C is still another cross-sectional schematic view of the light emitting diode device provided by the embodiments of the present disclosure.

Exemplarily, as shown in FIG. 3A, the light emitting diode device 100 comprises a support structure 9, a light emitting diode 12, a first electrode 801 and a second electrode 802. The light emitting diode 12 is provided on the support structure 9. The support structure 9 is, for example, a bracket, and is made of, for example, an inorganic material (e.g., ceramic) or an organic material (e.g., plastic). For example, the support structure 9 includes an accommodation portion 902 surrounded by a sidewall, a cross section of the accommodation portion 902 has a trapezoidal shape. For example, the light emitting diode 12 is provided in the accommodation portion 902, for example, the light emitting diode 12 is provided at a bottom of the accommodation portion 902. For example, the light emitting diode device 100 further comprises a light emitting diode chip 11 provided on the support structure, the light emitting diode chip 11 includes the light emitting diode 12 and a substrate on which the light emitting diode 12 is mounted (for example, a substrate provided with a circuit). The light emitting diode 12 for example is a single light emitting diode, or the light emitting diode 12 for example comprises a plurality of light emitting diodes connected with each other in series or in parallel. The first electrode 801 and the second electrode 802 are provided at the bottom of the support structure 9, for connecting the light emitting diode 12 to a power source so that the light emitting diode 12 emits light. The first electrode 801 and the second electrode 802 respectively include a first end and a second end. The light emitting diode support structure 9 includes an outer contour 901 extending in a vertical direction (i.e. a second direction) as shown in FIG. 3A. The first end of the first electrode 801 and the first end of the second electrode 802 respectively extend from the support structure 9 and beyond the outer contour 901 at the bottom of the support structure 9, i.e., the first end of the first electrode 801 and the first end of the second electrode 802 respectively extend beyond the outer contour 901 in a horizontal direction (i.e a first direction) as shown in FIG. 3A. In the case that the light emitting diode device 100 is provided in a light source structure, the structure of the first electrode 801 and the second electrode 802 allows the first electrode 801 and the second electrode 802 to be combined with a circuit board or other components in many ways, so that the light emitting diode device 100 is not limited to being provided on a surface of the circuit board and the performance of the light source structure is optimized. The second end of the first electrode 801 and the second end of the second electrode 802 are respectively electrically connected with the light emitting diode 12. For example, the second end of the first electrode 801 and the second end of the second electrode 802 are respectively electrically connected with the light emitting diode chip 11 so as to further be electrically connected with the light emitting diode 12.

For example, the accommodation portion 902 of the support structure 9 is bowl-shaped, the accommodation portion 902 includes a bottom supporting plane 6 (or, a bottom supporting frame) and the side wall having a curved surface. For example, the accommodation portion 902 does not include the bottom supporting plane or the side wall does not have the curved surface, so that the accommodation portion 902 forms a frame as a whole. The light emitting diode chip 11 for example is provided on the bottom supporting plane or the bottom supporting frame.

For example, the first electrode 801 and the second electrode 802 respectively include a first portion parallel to the bottom of the support structure 9 and a bent portion, the first portion and the bent portion of the first electrode 801 are connected with each other, and the first portion and the bent portion of the second electrode 802 are connected with each other. For example, in an example shown in FIG. 3A, the support structure 9 is a pillar. The first portion of the first electrode 801 and the first portion of the second electrode 802 are parallel to the bottom of the support structure 9 and are provided outside the support structure 9, and the first portion of the first electrode 801 and the first portion of the second electrode 802 respectively extend in the first direction and beyond the outer contour 901 of the bottom of the support structure 9. The bent portion of the first electrode 801 and the bent portion of the second electrode 802 respectively extend from an inner portion of the support structure 9 in a second direction and beyond a contour 903 of the bottom of the support structure 9. The contour 903 of the bottom of the support structure 9 extends in the first direction. For example, the first portion and the second portion of the first electrode 801 are integrally formed and the first portion and the second portion of the second electrode 802 are integrally formed, which is advantageous for reducing resistance at the connection position of the first portion and the second portion as compared with non-integral structure.

For example, the light emitting diode device 100 further comprises a fluorescent layer 13 provided above the light emitting diode 12. A type of fluorescent powder of the fluorescent layer 13 for example is determined according to a wavelength range of the light emitted by the light emitting diode 12, so that light emitted by the organic light emitting diode device 100 is a desired light. For example, in the case that the light emitting diode device 100 is used for displaying, the light emitted from the light emitting diode 12 is adjusted by the fluorescent layer 13 so that the light is comfortable to human eyes. During an application of the organic light emitting diode device 100, current flowing through the organic light emitting diode 12 for example is controlled by selecting a material for fabricating the organic light emitting diode 12 and by using a driving circuit , so that the wavelength range of the light emitted by the organic light emitting diode 12 is controlled. In this way, an effect of controlling a color of the light emitted by the organic light emitting diode 12 is achieved. As a result, a colored light is obtained, and thus is used in, for example, display boards, billboards, and the like.

For example, as shown in FIG. 3A, the light emitting diode device 100 further comprise a reflection structure 20, and a reflective surface of the reflection structure 20 and a light emission surface of the light emitting diode 12 have an included angle. For example, the included angle is greater than or equal to 90 degrees and less than 180 degrees. In this way, a part of the light emitted by the light emitting diode 12 is reflected by the reflection structure 20 to change its emergent direction, so that it is possible to control the emergent direction of light according to needs and the light utilization efficiency is improved. For example, the reflection structure 20 is a reflective layer coated on an inner surface of the accommodation portion 902. For example, the reflective layer has a smooth surface, or has a microstructure such as a concavo-convex structure, or is a reflective cover provided on the accommodation portion 902, etc. Those skilled in the art may design the reflection structure 20 according to a specific structure of the support structure 9 and a position of the light emitting diode 12.

For example, a shape of the support structure 9 is a pillar, a cylinder or a prism. As shown in FIG. 3A, the support structure 9 is a pillar, and its outer contour 901 is a curved surface, and the accommodation portion 902 has a curved inner surface. Of course, the support structure 9 may be in a shape of a bracket.

Difference between the structure shown in FIG. 3B and the structure shown in FIG. 3A is that, the support structure 9 is a bracket, and its outer contour 901 is composed of stripe-shaped sticks. In addition, the bent portion of the first electrode 801 and the bent portion of the second electrode 802 do not extend beyond the bottom contour 903 of the support structure 9 in the second direction; the first portion of the first electrode 801 and the first portion of the second electrode 802 extend from the inner portion of the supporting frame and beyond the outer contour 901 in the first direction. Other structures of the light emitting diode device 100 shown in FIG. 3B are the same as those shown in FIG. 3A.

For example, the first electrode 801 and the second electrode 802 respectively are in a straight strip shape, and extend in the direction (i.e., the first direction) parallel to the bottom of the support structure 9. Exemplarily, as shown in FIG. 3C, both the first electrode 801 and the second electrode 802 are in the straight strip shape, and extend from the inner portion of the support structure 9 and beyond the outer contour 901 in the first direction. Other structures of the light emitting diode device 100 shown in FIG. 3C are the same as those shown in FIG. 3A.

In the embodiments of the present disclosure, the first electrode and the second electrode are made of a conductive material, for example, a metal material (copper or copper alloy, aluminum or aluminum alloy). Of course, the material of the first electrode and the second electrode is not limited to the types as listed above.

It should be noted that, with respect to a way in which the first electrode and the second electrode are electrically connected with the light emitting diode chip, those skilled in the art may design according to the actual needs. For example, the first electrode and the second electrode are electrically connected with the light emitting diode chip by using a metal wire (e.g., a gold wire or a silver wire), or other suitable ways of electrical connection may also be selected, which will not be limited by the present disclosure.

The light emitting diode device provided by the embodiments of the present disclosure may be used as various light sources, for example, may be used as a backlight of a display device, a daily lighting, a decorative lamp, and the like.

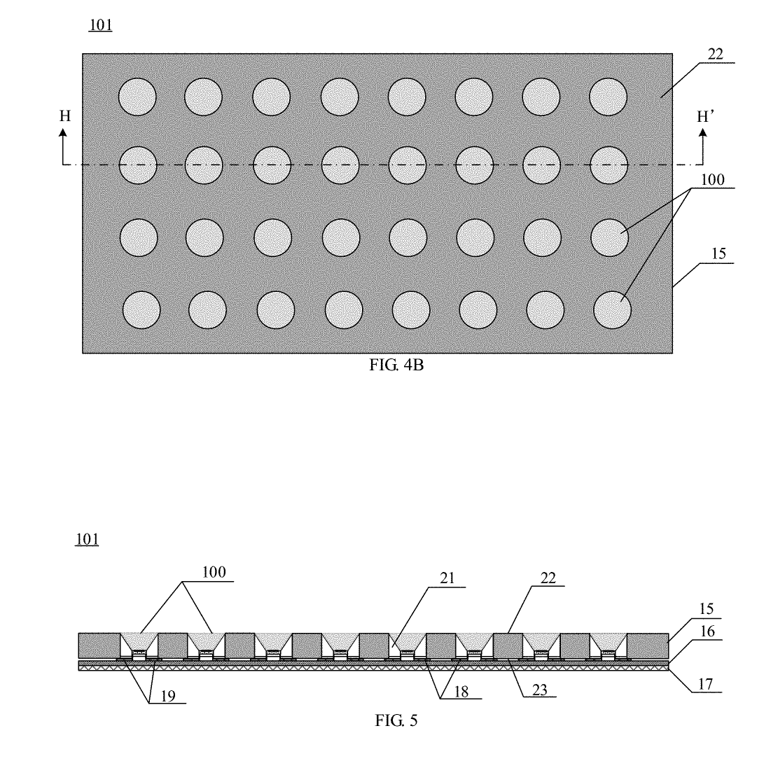

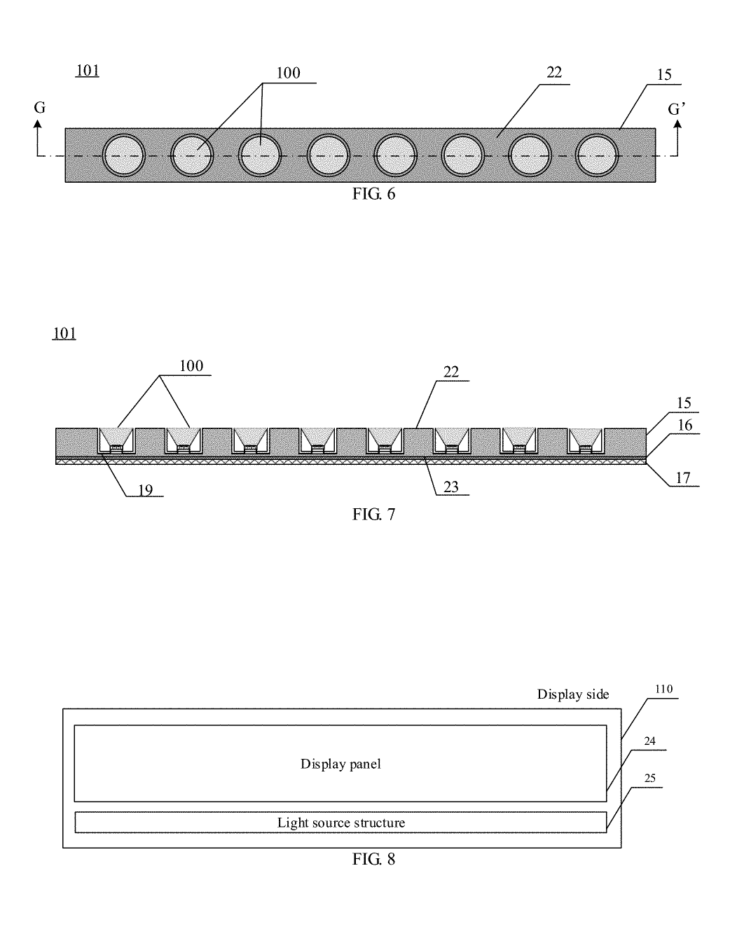

FIG. 4A is a plane schematic view of a light source structure provided by the embodiments of the present disclosure; FIG. 4B is another plane schematic view of the light source structure provided by the embodiments of the present disclosure; FIG. 5 is a cross-sectional schematic view taken along a line I-I′ in FIG. 4A or H-H′ in FIG. 4B; FIG. 6 is another plane schematic view of the light source structure provided by the embodiments of the present disclosure; and FIG. 7 is a cross-sectional schematic view taken along a line G-G′ of FIG. 6. A thickness of the light source structure is relatively small, which facilitates the fabrication of light and thin product.

As shown in FIG. 5, the light source structure 101 comprises a plurality of light emitting diode devices 100 as described above and a circuit board 15. For example, a via hole 21 penetrating through the circuit board 15 is provided in the circuit board 15, at least a portion of the light emitting diode device 100 is provided in the via hole so as to embed the light emitting diode device 100 in the circuit board 15. For example, as shown in FIG. 5, the support structure 9 and the light emitting diode 12 are located in the via hole 21, and the first end of the first electrode 801 and the first end of the second electrode 802 are located on a side of the circuit board 15 opposite to a first surface of the circuit board 15. For example, the support structure 9, the light emitting diode 12 and the fluorescent layer 13 are all located in the via hole 21, such structure is more conducive to reduce the thickness of the light source structure 101 and protect the support structure 9, the light emitting diode 12 and the fluorescent layer 13 as compared with a case that one portion of the support structure 9 is located inside the via hole 21 while the other portion of the support structure 9 is located outside the via hole 21 (for example, the other portion of the support structure 9 protrudes from the first surface the circuit board 15 or the surface opposite to the first surface). As shown in FIG. 5, the circuit board 15 is provided with a plurality of via holes 21 penetrating through the circuit board 15, the light emitting diode device 100 is provided in each via hole 21, a light emission surface of the light emitting diode device 100 has a same orientation as the first surface 22 of the circuit board 15, for example, the light emission surface of the light emitting diode device 100 and the first surface 22 of the circuit board 15 face upwardly in FIG. 5. As compared with the light source structure (as shown in FIG. 2) in which the light emitting diode device is provided on the first surface of the circuit board, the thickness of the light source structure according to the embodiments of the present disclosure is reduced, which facilitates fabrication of light and thin product.

For example, a plurality of contact pads 19 are provided on a second surface 23 of the circuit board 15 opposite to the first surface 22 of the circuit board 15, the first electrode and the second electrode of the light emitting diode device 100 are configured so that the first end of the first electrode and the first end of the second electrode are electrically connected with the contact pads 19. For example, the first electrode and the second electrode of each light emitting diode device 100 are soldered to the corresponding contact pads. For example, the first electrode is soldered to the contact pad electrically connected with a positive terminal of the power source, and the second electrode is soldered to the contact pad electrically connected with a negative terminal of the power source, so as to supply the electrical energy to the light emitting diode device.

For example, the second surface 23 of the circuit board 15 is further provided with an insulating member 18 covering an exposed portion of the first end of the first electrode and an exposed portion of the first end of the second electrode. In this way, it is possible to prevent the exposed portion of the first end of the first electrode and the exposed portion of the first end of the second electrode from being interfered by electrical signals outside the contact pads. For example, the insulating member 18 comprises a plurality of portions spaced from each other as shown in FIG. 5 to cover the exposed portion of the first end of the first electrode and the exposed portion of the first end of the second electrode. In other examples, the insulating member 18 for example is a continuous insulating layer covering the second surface 23 of the circuit board 15. For example, the insulating member 18 is made of an inorganic insulating material (silicon nitride, quartz, mica or asbestos, etc.), or an organic insulating material (resin, polyvinyl chloride, etc.), or a combination of two or more insulating materials. For example, the insulating member 18 is made of an insulating material with good thermal conductivity so as to facilitate heat dissipation of the light emitting diode, such as, an inorganic-filled polyethylene composite material or inorganic-filled phenolic resin composite material with high thermal conductivity, and the like. Materials for forming the insulating member 18 are not limited to the types as listed above, which will not be limited in the embodiments of the present disclosure.

For example, the light source structure 101 further comprises a heat conductive layer 16 provided on the second surface 23 to facilitate heat dissipation, so that heat is conducted more effectively. For example, the heat conductive layer 16 is a thermal adhesive adhered to the second surface 23 of the circuit board 15. The first electrode and the second electrode of the light emitting diode is in contact with the heat conductive layer 16. In the light source structure 101, heat generated by the light emitting diode sequentially passes through the light emitting diode chip and the first and second electrodes to the heat conductive layer 16; in this case, heat does not need to pass through the circuit board 15. In this way, as compared with the light source structure in which the light emitting diode is provided on the circuit board, the heat dissipation path of the light emitting diode is shortened, the heat dissipation speed is improved, and the service life of the light emitting diode is prolonged.

For example, the light source structure 101 further comprises a heat dissipation layer 17 covering the heat conductive layer 16 to facilitate heat dissipation. Heat generated by the light emitting diode sequentially passes through the light emitting diode chip, the first and second electrodes and the heat conductive layer 16 to the heat dissipation layer 17, and then is dissipated to an ambient environment via the heat dissipation layer 17.

For example, a plane shape of the light source structure 101 is an elongated shape or a planar shape, respectively as shown in FIG. 4A and FIG. 4B, so as to meet different application requirements. In FIG. 4A and FIG. 4B, the plane shape of the light source structure 101 is a rectangle, but it is not limited to the rectangle and may be other polygons, a circle, an ellipse or any other irregular patterns. Specific shapes of the light source structure 101 may be designed according to actual needs, which will not be limited in the embodiments of the present disclosure.

For example, the circuit board 15 further comprises at least one groove, and the light emitting diode device is provided in the groove so as to embed the light emitting diode device into the circuit board 15. In the example shown in FIG. 6 and FIG. 7, the circuit board 15 comprises a plurality of grooves, the light emitting diode device 100 is provided in each groove, and the light emission surface of the light emitting diode device 100 has a same orientation as that of the first surface of the circuit board 15. In this way, the light emitting diode device is embedded into the circuit board 15, so as to reduce the thickness of the light source structure 101.

For example, as shown in FIG. 7, a plurality of contact pads are provided in the groove; for example, contact pads respectively electrically connected with the positive terminal and a negative terminal of the power source are provided in each groove, the contact pads are respectively electrically connected with the first end of the first electrode and the first end of the second electrode of the light emitting diode device 100. In this way, during the circuit board 15 is powered on, the light emitting diode device 100 is powered on and works.

It should be noted that, in the examples shown in FIG. 6 and FIG. 7, since the first end of the first electrode and the first end of the second electrode are located in the groove and thus are protected, it is not necessary to provide the insulating member covering the first end of the first electrode and the first end of the second electrode. In addition, the heat conductive layer 16 and the heat dissipation layer 17 are the same as those in the example shown in FIG. 5, for which the description above can be referred to.

For example, in the above-described embodiments, the plurality of via holes or grooves are uniformly distributed in the circuit board 15, so that respective regions of the light source structure emit uniform and consistent light.

The embodiments of the present disclosure further provide an electronic apparatus, and the electronic apparatus comprises any one of the light source structures as described above.

The electronic apparatus is, for example, an illuminating device, the illuminating device includes any one of the light source structures as described above; the illuminating device emits monochromatic light, for example, white light, red light, green light or blue light, or emits mixed light, for example, light obtained by mixing red, green and blue (RGB) lights. The illuminating device is, for example, a lighting lamp, a display board, a billboard, and the like.

The electronic apparatus is, for example, a display device. FIG. 8 a schematic view of the display device provided by the embodiments of the present disclosure. As shown in FIG. 8, for example, the light source structure 25 is provided on a non-display side of a display panel 24. Light emitted by the light source structure 25 is incident on the display panel 24, i.e., the light source structure 25 serves as a backlight of the display device 110. The backlight 25 for example further include a backlight board and a reflecting layer (not shown), and the like. For example, the display device according to the embodiments of the present disclosure is a liquid crystal display device or other display device that needs the backlight.

It should be noted that, FIG. 8 only shows components of the display device 110 related to the light source structure, and with respect to other structures, those skilled in the art may refer to the conventional art.

The foregoing embodiments merely are exemplary embodiments of the present disclosure, and not intended to define the scope of the present disclosure, and the scope of the present disclosure is determined by the appended claims.

The present application claims priority of the Chinese Patent Application No. 201721049430.8 filed on Aug. 21, 2017, the disclosure of which are incorporated herein by its reference in its entirety as part of the present application.

1. A light emitting diode device, comprising:
a support structure;
at least one light emitting diode, provided on the support structure; and
a first electrode and a second electrode, provided at a bottom of the support structure and respectively electrically connected with the light emitting diode,
wherein, the first electrode and the second electrode respectively include a first end, and the first end of the first electrode and the first end of the second electrode extend beyond an outer contour of the bottom of the support structure in a direction parallel to the bottom of the support structure.

2. The light emitting diode device according to claim 1, wherein, the first electrode and the second electrode are of a straight strip shape and extend in the direction parallel to the bottom of the support structure.

3. The light emitting diode device according to claim 1, wherein,
the first electrode and the second electrode respectively include a first portion and a bent portion connected with each other,
the first portion of the first electrode and the first portion of the second electrode are parallel to the bottom of the support structure, and extend beyond the outer contour of the bottom of the support structure in the direction parallel to the bottom of the support structure, and
the bent portion of the first electrode and the bent portion of the second electrode extend from an inner portion of the support structure beyond the bottom of the support structure in a direction perpendicular to the bottom of the support structure.

4. The light emitting diode device according to claim 1, wherein,
the first electrode and the second electrode respectively include a first portion and a bent portion connected with each other,
the first portion of the first electrode and the first portion of the second electrode are parallel to the bottom of the support structure, and extend beyond the outer contour of the bottom of the support structure in the direction parallel to the bottom of the support structure, and
the bent portion of the first electrode and the bent portion of the second electrode extend from an inner portion of the support structure but not beyond the bottom of the support structure in a direction perpendicular to the bottom of the support structure.

5. The light emitting diode device according to claim 1, further comprising a fluorescent layer provided on the light emitting diode.

6. The light emitting diode device according to claim 1, further comprising a light emitting diode chip provided on the support structure, and the light emitting diode chip including the light emitting diode.

7. The light emitting diode device according to claim 1, further comprising a reflection structure, and a reflective surface of the reflection structure and a light emission surface of the light emitting diode having an included angle.

8. The light emitting diode device according to claim 1, wherein, the support structure is a pillar or a bracket.

9. A light source structure, comprising: the light emitting diode device according to claim 1 and a circuit board, wherein,
the light emitting diode device is provided in the circuit board, so that the light emitting diode device is embedded in the circuit board.

10. The light source structure according to claim 9, wherein, the circuit board comprises a groove or a via hole penetrating through the circuit board, at least a portion of the light emitting diode device is provided in the via hole or the groove, and a light emission surface of the light emitting diode has a same orientation as that of the first surface of the circuit board.

11. The light source structure according to claim 10, wherein, the support structure and the light emitting diode are located in the via hole, the first end of the first electrode and the first end of the second electrode are located on a side of the circuit board opposite to the first surface of the circuit board.

12. The light source structure according to claim 10, wherein, a plurality of contact pads are provided on a second surface of the circuit board opposite to the first surface of the circuit board, and the contact pads are respectively electrically connected with the first end of the first electrode and the first end of the second electrode; or,
a plurality of contact pads are provided in the groove, and the contact pads are respectively electrically connected with the first end of the first electrode and the first end of the second electrode.

13. The light source structure according to claim 12, wherein, an insulating member is provided on the second surface of the circuit board to cover an exposed portion of the first end of the first electrode and an exposed portion of the first end of the second electrode.

14. The light source structure according to claim 10, further comprising a heat conductive layer provided on a second surface of the circuit board opposite to the first surface of the circuit board.

15. The light source structure according to claim 14, further comprising a heat dissipation layer covering the heat conductive layer.

16. An electronic apparatus, comprising the light source structure according to claim 9.

17. The electronic apparatus according to claim 16, wherein, the electronic apparatus is a display device, and the light source structure is configured as a backlight of the display device.
